(19) United States
(12) Patent Application Publication
(10) Pub. No.: US 2016/0276472 A1
(43) Pub. Date: Sep. 22, 2016

(54) Semiconductor Device and Manufacturing Method Thereof

(71) Applicant: Hermes-Epitek Corp., Taipei City (TW)

(72) Inventors: Takashi KOBAYASHI, Hsinchu City (TW); Po-Jung LIN, Hsinchu City (TW); Che-Lin CHEN, Tainan City (TW)

(21) Appl. No.: 14/660,494

(22) Filed: Mar. 17, 2015

(51) Int. Cl. H01L 29/778; H01L 29/66; H01L 29/205; H01L 21/02; H01L 29/20; H01L 29/207

(52) U.S. Cl. CPC H01L 29/7783; H01L 29/2003; H01L 29/207; H01L 29/205; H01L 21/02458; H01L 21/0254; H01L 21/02378; H01L 21/02381; H01L 21/0242; H01L 29/66462

(57) ABSTRACT

A semiconductor device includes a substrate, a buffer layer and a device layer. The buffer layer is deposited on the substrate and comprises at least one gallium nitride (GaN) epitaxy layer and at least one insertion layer deposited on the GaN epitaxy layer, wherein the GaN epitaxy layer adjacent to an interface between the GaN epitaxy layer and the upper insertion layer is doped with a trapping electron element. The device layer is formed on the buffer layer. According to the foregoing structure, electrons in the GaN epitaxy layer is trapped and then the electron mobility is reduced, so that leakage current from the buffer layer is suppressed and then the performance of the semiconductor device can be enhanced. A manufacturing method for the semiconductor device is also disclosed.

### BACKGROUND OF THE INVENTION

1. Field of the Invention

The present invention relates to a semiconductor device and a manufacturing method thereof, and more particularly to a semiconductor device with lower leakage current and a manufacturing method thereof.

2. Description of the Prior Art

In high power and high frequency device application, the high electron mobility transistor (HEMT) is a common structure. The HEMT structure generates a region where electrons have very high mobility. These high mobility electrons can give superior high frequency performance.

Aluminum gallium nitride/gallium nitride (AlGaN/GaN) structure is very popular in HEMT device. Firstly, this is due to the advantages of GaN material characteristic with high band gap, high breakdown voltage, high electron mobility and high thermal conductivity etc. Furthermore, heterojunction of AlGaN/GaN can produce two dimensional electron gas (2DEG) which is a gas of electrons free to move with higher mobility. The AlGaN is used as a barrier layer and the GaN is used as a channel layer.

It is known that high electron mobility devices typically require semi-insulating substrates having relatively high resistivity and the thicker GaN epitaxy layer is needed to improve breakdown voltage of power devices. Based on growing thicker GaN epitaxy layer on silicon (Si) substrate, there are many kind of transition layer between the GaN epitaxy layer and Si substrate, such as multi layer, insertion layer, or super lattice structures. However, these transition layers will generate serious problem of leakage current in the power device. Accordingly, how to suppress the phenomenon of leakage current in the epitaxy layer is a major issue.

### SUMMARY OF THE INVENTION

The present invention is directed to a semiconductor device and a manufacturing method, which dopes trapping electron element in the buffer layer between the substrate and the device layer to avoid the formation of an unexpected two dimensional electron gas (2DEG) in the buffer layer, thereby suppressing the leakage current through the path of 2DEG.

In one embodiment, the proposed semiconductor device includes a substrate, a buffer layer and a device layer. The buffer layer is deposited on the substrate and comprises at least one gallium nitride (GaN) epitaxy layer and at least one insertion layer deposited on the GaN epitaxy layer, wherein the GaN epitaxy layer adjacent to an interface between the GaN epitaxy layer and the upper insertion layer is doped with a trapping electron element. The device layer is formed on the buffer layer.

In another embodiment, the proposed manufacturing method for a semiconductor device comprises: providing a substrate; forming a buffer layer on the substrate, wherein the buffer layer comprises at least one gallium nitride (GaN) epitaxy layer and at least one insertion layer deposited on the GaN epitaxy layer, and the GaN epitaxy layer adjacent to an interface between the GaN epitaxy layer and the upper insertion layer is doped with a trapping electron element; and forming a device layer on the buffer layer.

The objective, technologies, features and advantages of the present invention will become apparent from the following description in conjunction with the accompanying drawings wherein certain embodiments of the present invention are set forth by way of illustration and example.

### BRIEF DESCRIPTION OF THE DRAWINGS

The foregoing conceptions and their accompanying advantages of this invention will become more readily appreciated after being better understood by referring to the following detailed description, in conjunction with the accompanying drawings, wherein:

FIG. 1 is a diagram schematically illustrating a semiconductor device according to a first embodiment of the present invention;

FIG. 2 is a diagram schematically illustrating a semiconductor device according to a second embodiment of the present invention;

FIG. 3 is a diagram schematically illustrating a semiconductor device according to a third embodiment of the present invention;

FIG. 4 is a diagram schematically illustrating a semiconductor device according to a fourth embodiment of the present invention; and

FIG. 5 is a flowchart schematically illustrating a manufacturing method for a semiconductor device according to an embodiment of the present invention.

### DESCRIPTION OF THE PREFERRED EMBODIMENT

Various embodiments of the present invention will be described in detail below and illustrated in conjunction with the accompanying drawings. In addition to these detailed descriptions, the present invention can be widely implemented in other embodiments, and apparent alternations, modifications and equivalent changes of any mentioned embodiments are all included within the scope of the present invention and based on the scope of the Claims. In the descriptions of the specification, in order to make readers have a more complete understanding about the present invention, many specific details are provided; however, the present invention may be implemented without parts of or all the specific details. In addition, the well-known steps or elements are not described in detail, in order to avoid unnecessary limitations to the present invention. Same or similar elements in Figures will be indicated by same or similar reference numbers. It is noted that the Figures are schematic and may not represent the actual size or number of the elements. For clearness of the Figures, some details may not be fully depicted.

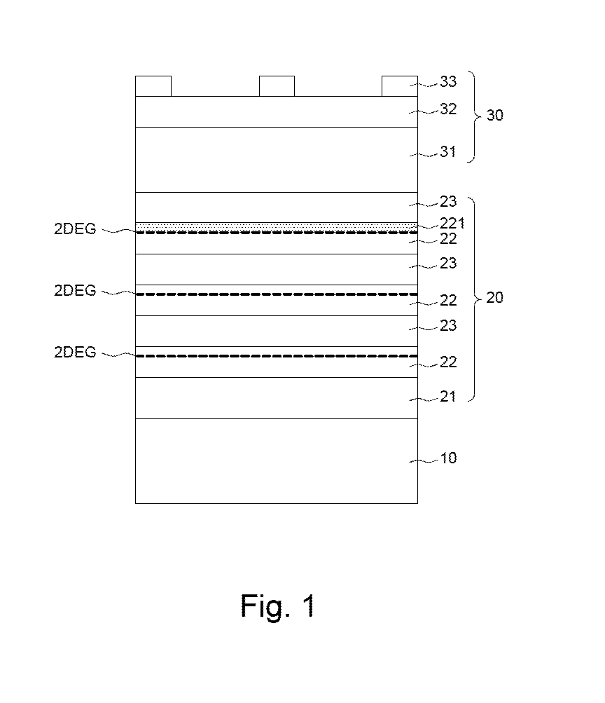

Referring to FIG. 1, a semiconductor device according to an embodiment of the present invention comprises a substrate 10, a buffer layer 20 and a device layer 30. In one embodiment, the substrate 10 may be a silicon (Si) substrate, a silicon carbide (SiC) substrate or a sapphire substrate. The buffer layer 20 is disposed on the substrate 10. The buffer layer 20 is able to improve the problem of lattice structure mismatch between the substrate 10 and the device layer 30. Therefore, in order to grow a thicker epitaxy layer on the substrate 10, such as growing thicker gallium nitride (GaN) epitaxy layer on Si substrate, the buffer layer 20 should be needed. The device layer 30 is formed on the buffer layer 20 to implement a function of the semiconductor device. For example, the device layer 30 comprises a channel layer 31, a barrier layer 32 and an electrode layer 33 including a source electrode, a gate electrode and a drain electrode. The detailed structure and composition material of the device layer 30 can be implemented with the conventional techniques and would be skipped here.

Continuing the above description, the buffer layer 20 comprises at least one GaN epitaxy layer 22 and at least one insertion layer 23 deposited on the GaN epitaxy layer 22. In the embodiment shown in FIG. 1, in order from the substrate 10 to the device layer 30, the buffer layer 20 comprises an initial layer 21 and a plurality of the GaN epitaxy layers 22 and the insertion layers 23 deposited in an interlacing manner. For example, the initial layer 21 may be aluminum nitride (AlN); the insertion layer 23 may be AlN or aluminum gallium nitride (AlGaN).

According to the foregoing structure, an unexpected two dimensional electron gas (2DEG) is generated at an interface between the GaN epitaxy layer 22 and the upper insertion layer 23, as shown in FIG. 1, and it will cause serious problem of leakage current in the power device. Therefore, in the present invention, the GaN epitaxy layer 22 adjacent to the interface between the GaN epitaxy layer 22 and the upper insertion layer 23 is doped with a trapping electron element 221. The trapping electron element 221 doped in the GaN epitaxy layer 22 will substitute Ga atoms in the GaN epitaxy layer 22, which will form a deep acceptor to trap electrons in the GaN epitaxy layer 22, so that the unexpected 2DEG will not be formed and then the leakage current through the path of 2DEG is suppressed. In one embodiment, the trapping electron element 221 may be at least one of iron (Fe), carbon (C) and magnesium (Mg). Preferably, the trapping electron element 221 may be the iron. With the interface between the GaN epitaxy layer 22 and the upper insertion layer 23 as a benchmark, the thickness of the GaN epitaxy layer 22 doped with the trapping electron element 221 is greater than 5 nm, preferably, greater than 10 nm. In one embodiment, a dopant concentration within a range of about 10¹⁶ to 10¹⁹ cm⁻³.

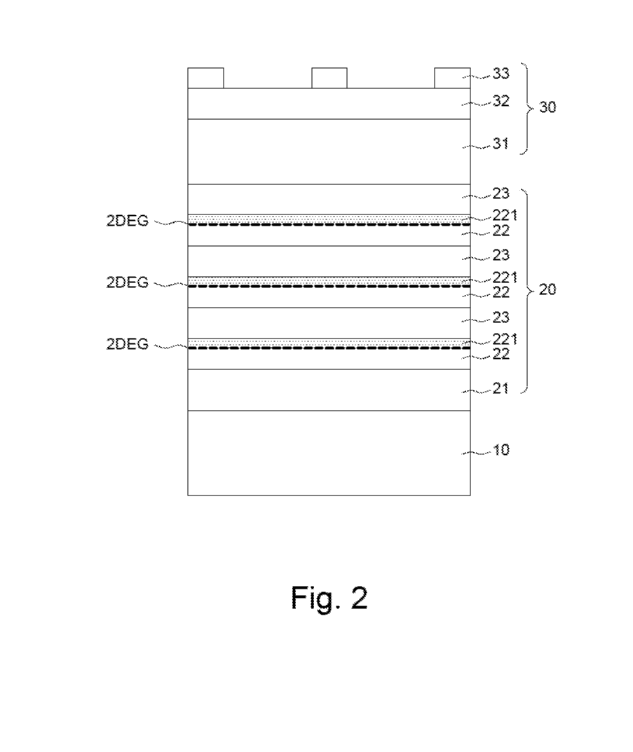

In the embodiment shown in FIG. 1, the trapping electron element 221 is doped in the GaN epitaxy layer 22 adjacent to the uppermost interface between the GaN epitaxy layer 22 and the upper insertion layer 23, but is not limited thereto. In one embodiment shown in FIG. 2, each of the GaN epitaxy layers 22 adjacent to the interface between the GaN epitaxy layer 22 and the upper insertion layer 23 is doped with the trapping electron element 221 to increase the effect of suppressing the leakage current.

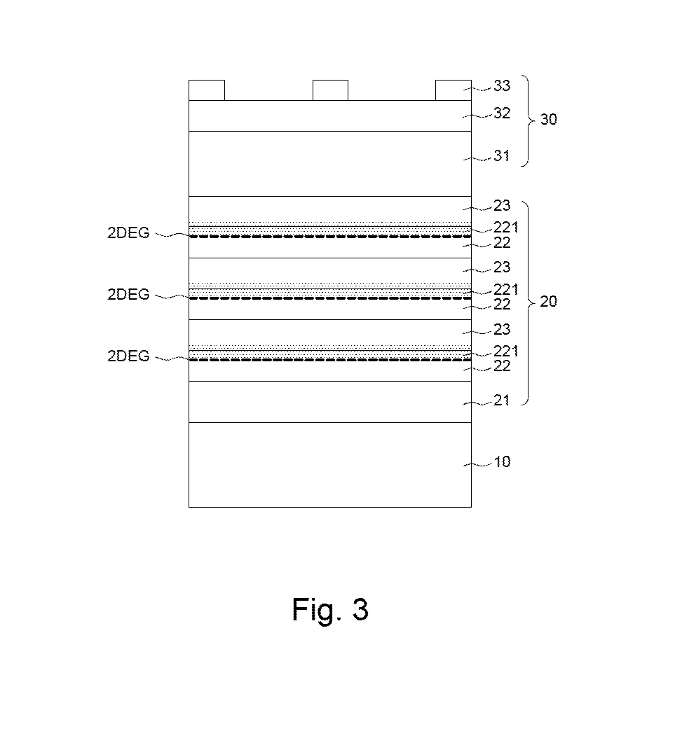

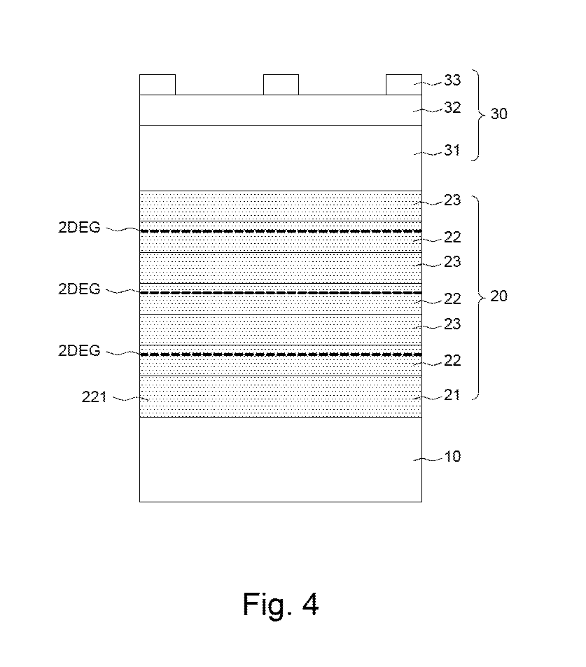

Referring to FIG. 3, in one embodiment, the insertion layer 23 adjacent to the interface between the insertion layer 23 and the lower GaN epitaxy layer 22 is also doped with the trapping electron element 221. In other words, the region doped with the trapping electron element 221 is across the interface between the GaN epitaxy layer 22 and the upper insertion layer 23. It should be noted that the trapping electron element 221 may be doped in the uppermost insertion layer 23 or each of the insertion layers 23. Referring to FIG. 4, in one embodiment, the trapping electron element 221 can be doped in each deposition layer of the buffer layer 20. For example, the deposition layers of the buffer layer 20 include the initial layer 21, the GaN epitaxy layers 22 and the insertion layers 23.

According to the foregoing structure, the trapping electron element 221 doped in the buffer layer 20 traps electrons to reduce the electron mobility, so that the unexpected 2DEG will not be formed at the interface between the GaN epitaxy layers 22 and the upper insertion layers 23 and thereby suppress the leakage current phenomenon in the buffer layer 20 and enhance the performance of semiconducting devices.

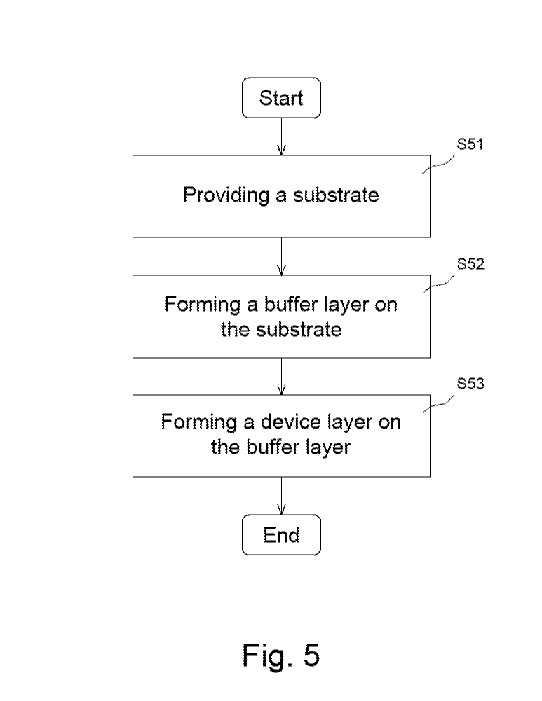

Referring to FIG. 1 and FIG. 5 for illustrating a manufacturing method for a semiconductor device according to an embodiment of the present invention, firstly, a substrate 10 is provided (S51), such as a Si substrate, a SiC substrate or a sapphire substrate. Secondly, a buffer layer 20 is formed on the substrate 10. As mentioned above, the buffer layer 20 comprises an initial layer 21 and a plurality of the GaN epitaxy layers 22 and the insertion layers 23 deposited in an interlacing manner. MN is formed for the initial layer 21 as an example for illustration. The initial layer 21 may be formed by a crystal growth method such as a metal organic vapor phase epitaxy (MOVPE) method with a mixed gas containing an aluminum element source gas (such as trimethylaluminum (TMA) gas) and a nitrogen element gas (such as ammonia (NH3) gas). Similarly, the GaN epitaxy layer 22 may be formed by the MOVPE method with a mixed gas containing a gallium element source gas (such as trimethylgallium (TMG) gas) and a nitrogen element gas (such as ammonia (NH3) gas). It can be understood that the trapping electron element 221 can be doped in the GaN epitaxy layer 22 by passing into the trapping electron element 221 while growing the GaN epitaxy layer 22. For example, Cp₂Fe (cyclopentadienyl iron, ferrocene) may be used for a source of Fe. The formation of the insertion layers 23 is the same with the initial layer 21. Finally, a device layer 30 is formed on the buffer layer 20 to accomplish the semiconductor device shown in FIG. 1. The process of the device layer 30 can be implemented with the conventional techniques and would be skipped here.

To summarize the foregoing descriptions, according to the semiconductor device and manufacturing method of the present invention, the trapping electron element is doped in the buffer layer between the substrate and the device layer, so that electrons in the GaN epitaxy layer is trapped and then the electron mobility is reduced. In other words, an unexpected 2DEG will not be formed at the interface between the GaN epitaxy layer and the upper insertion layer, i.e. there is no 2DEG as the leakage current path, so that the performance of the semiconductor device can be enhanced.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the scope of the appended claims.

What is claimed is:

1. A semiconductor device comprising:
a substrate;
a buffer layer deposited on the substrate and comprising at least one gallium nitride (GaN) epitaxy layer and at least one insertion layer deposited on the GaN epitaxy layer, wherein the GaN epitaxy layer adjacent to an interface between the GaN epitaxy layer and the upper insertion layer is doped with a trapping electron element; and
a device layer formed on the buffer layer.

2. The semiconductor device according to claim 1, wherein the insertion layer adjacent to the interface between the insertion layer and the lower GaN epitaxy layer is doped with the trapping electron element.

3. The semiconductor device according to claim 1, wherein the buffer layer comprises a plurality of the GaN epitaxy layers and the insertion layers deposited in an interlacing manner, and each of the GaN epitaxy layers adjacent to the interface between the GaN epitaxy layer and the upper insertion layer is doped with the trapping electron element.

4. The semiconductor device according to claim 1, wherein the buffer layer comprises a plurality of the GaN epitaxy layers and the insertion layers deposited in an interlacing manner, and each of the insertion layers adjacent to the interface between the insertion layer and the lower GaN epitaxy layer is doped with the trapping electron element.

5. The semiconductor device according to claim 1, wherein the buffer layer comprises a plurality of deposition layers comprising the GaN epitaxy layer and the insertion layer, and each of the deposition layers is doped with the trapping electron element.

6. The semiconductor device according to claim 1, wherein the thickness of the GaN epitaxy layer doped with the trapping electron element is greater than 5 nm.

7. The semiconductor device according to claim 1, wherein the trapping electron element comprises at least one of iron, carbon and magnesium.

8. The semiconductor device according to claim 1, wherein the insertion layer comprises aluminum nitride (AlN) or aluminum gallium nitride (AlGaN).

9. The semiconductor device according to claim 1, wherein the buffer layer further comprises an initial layer deposited on the substrate, and the GaN epitaxy layer is deposited on the initial layer.

10. The semiconductor device according to claim 9, wherein the initial layer comprises aluminum nitride (AlN).

11. The semiconductor device according to claim 1, wherein the substrate comprises silicon (Si) substrate, a silicon carbide (SiC) substrate or a sapphire substrate.

12. A manufacturing method for a semiconductor device comprising:
providing a substrate;
forming a buffer layer on the substrate, wherein the buffer layer comprises at least one gallium nitride (GaN) epitaxy layer and at least one insertion layer deposited on the GaN epitaxy layer, and the GaN epitaxy layer adjacent to an interface between the GaN epitaxy layer and the upper insertion layer is doped with a trapping electron element; and
forming a device layer on the buffer layer.

13. The manufacturing method for the semiconductor device according to claim 12, wherein the insertion layer adjacent to the interface between the insertion layer and the lower GaN epitaxy layer is doped with the trapping electron element.

14. The manufacturing method for the semiconductor device according to claim 12, wherein the buffer layer comprises a plurality of the GaN epitaxy layers and the insertion layers deposited in an interlacing manner, and each of the GaN epitaxy layers adjacent to the interface between the GaN epitaxy layer and the upper insertion layer is doped with the trapping electron element.

15. The manufacturing method for the semiconductor device according to claim 12, wherein the buffer layer comprises a plurality of the GaN epitaxy layers and the insertion layers deposited in an interlacing manner, and each of the insertion layers adjacent to the interface between the insertion layer and the lower GaN epitaxy layer is doped with the trapping electron element.

16. The manufacturing method for the semiconductor device according to claim 12, wherein the buffer layer comprises a plurality of deposition layers comprising the GaN epitaxy layer and the insertion layer, and each of the deposition layers is doped with the trapping electron element.

17. The manufacturing method for the semiconductor device according to claim 12, wherein the thickness of the GaN epitaxy layer doped with the trapping electron element is greater than 5 nm.

18. The manufacturing method for the semiconductor device according to claim 12, wherein the trapping electron element comprises at least one of iron, carbon and magnesium.

19. The manufacturing method for the semiconductor device according to claim 12, wherein the insertion layer comprises aluminum nitride (AlN) or aluminum gallium nitride (AlGaN).

20. The manufacturing method for the semiconductor device according to claim 12, wherein the buffer layer further comprises an initial layer deposited on the substrate, and the GaN epitaxy layer is deposited on the initial layer.

21. The manufacturing method for the semiconductor device according to claim 20, wherein the initial layer comprises aluminum nitride (AlN).

22. The manufacturing method for the semiconductor device according to claim 12, wherein the substrate comprises silicon (Si) substrate, a silicon carbide (SiC) substrate or a sapphire substrate.
